(19) United States
(12) Patent Application Publication
(10) Pub. No.: US 2024/0363356 A1
(43) Pub. Date: Oct. 31, 2024

(54) ETCHING METHOD AND METHOD FOR PRODUCING SEMICONDUCTOR ELEMENT

(71) Applicant: Resonac Corporation, Tokyo (JP)

(72) Inventor: Kazuma MATSUI, Tokyo (JP)

(73) Assignee: Resonac Corporation, Tokyo (JP)

(21) Appl. No.: 18/682,767

(22) PCT Filed: Jul. 5, 2022
(86) PCT No.: PCT/JP2022/026719

§ 371 Date: Feb. 9, 2024

(30) Foreign Application Priority Data
Aug. 10, 2021 (JP) 2021-130524

(51) Int. Cl. H01L 21/3065; C09K 13/00

(52) U.S. Cl. CPC H01L 21/3065; C09K 13/00

(57) ABSTRACT

There is provided an etching method capable of selectively etching an etching object as compared with a non-etching object. An etching method includes an etching step of bringing an etching gas containing nitrosyl fluoride into contact with a member to be etched (12) having an etching object subject to etching by the etching gas and a non-etching object not subject to etching by the etching gas, and selectively etching the etching object as compared with the non-etching object without using plasma. The etching object contains at least one of silicon and silicon germanium represented by the chemical formula Si₁₋ₓGeₓ and the non-etching object contains at least one of germanium and silicon germanium represented by the chemical formula Si_{1-y}Ge_{y}. In both the chemical formulae, x is 0 or more and less than 1, y is more than 0 and 1 or less, and x is smaller than y.

### TECHNICAL FIELD

The present invention relates to an etching method and a method for producing a semiconductor element.

### BACKGROUND ART

To enhance the performance of semiconductor devices, a technology has been demanded which selectively etches an etching object containing at least one of silicon (Si) and silicon germanium (Si₁₋ₓGeₓ) as compared with a non-etching object containing at least one of germanium (Ge) and silicon germanium (Si_{1-y}Ge_{y}). Herein, in both the chemical formulae above, x is 0 or more and less than 1, y is more than 0 and 1 or less, and x is smaller than y.

Methods for etching the etching object containing silicon include a dry etching method using an etching gas containing nitrosyl fluoride (NOF) and not using plasma. For example, PTL 1 discloses a method for generating nitrosyl fluoride by mixing nitric oxide (NO) and a fluorine gas (F₂), and selectively etching polysilicon as compared with silicon nitride. Further, PTL 2 discloses a method for generating nitrosyl fluoride by mixing a monofluoro interhalogen gas and nitric oxide, and selectively etching polysilicon as compared with silicon nitride.

### CITATION LIST

### Patent Literatures

PTL 1: JP 2014-236055 A

PTL 2: WO 2018/181104

### SUMMARY OF INVENTION

### Technical Problem

However, the technology of selectively etching the etching object containing silicon as compared with the non-etching object containing germanium is not known. It is an object of the present invention to provide an etching method capable of selectively etching the etching object containing at least one of silicon and silicon germanium represented by the chemical formula Si₁₋ₓGeₓ as compared with the non-etching object containing at least one of germanium and silicon germanium represented by the chemical formula Si_{1-y}Ge_{y}, and a method for producing a semiconductor element. In both the chemical formulae above, x is 0 or more and less than 1, y is more than 0 and 1 or less, and x is smaller than y.

### Solution to Problem

To solve the above-described problem, one aspect of the present invention is as described in [1] to [8] below.

[1] An etching method including: an etching step of bringing an etching gas containing nitrosyl fluoride into contact with a member to be etched having an etching object subject to etching by the etching gas and a non-etching object not subject to etching by the etching gas, and selectively etching the etching object as compared with the non-etching object without using plasma, in which the etching object contains at least one of silicon and silicon germanium represented by the chemical formula Si₁₋ₓGeₓ and the non-etching object contains at least one of germanium and silicon germanium represented by the chemical formula Si_{1-y}Ge_{y}, and in both the chemical formulae above, x is 0 or more and less than 1, y is more than 0 and 1 or less, and x is smaller than y.

[2] The etching method according to [1], in which x in the chemical formula above is 0 or more and 0.1 or less.

[3] The etching method according to [1] or [2], in which y in the chemical formula above is more than 0.1 and 1 or less.

[4] The etching method according to [1], in which y in the chemical formula above is 0.2 or more and 1 or less.

[5] The etching method according to any one of [1] to [4], in which a temperature condition of the etching step is −50° C. or more and 40°° C. or less.

The etching method according to any one of [1] to [5], in which the etching gas is a gas containing only nitrosyl fluoride or a mixed gas containing nitrosyl fluoride and a diluent gas.

[7] The etching method according to [6], in which the diluent gas is at least one selected from a nitrogen gas, helium, argon, neon, krypton, and xenon.

[8] A method for producing a semiconductor element, the method producing a semiconductor element using the etching method according to any one of [1] to [7], and t

he member to be etched being a semiconductor substrate having the etching object and the non-etching object,

the method including: a treatment step of removing at least a part of the etching object from the semiconductor substrate by the etching.

### Advantageous Effects of Invention

The present invention can selectively etch the etching object containing at least one of silicon and silicon germanium represented by the chemical formula Si₁₋ₓGeₓ as compared with the non-etching object containing at least one of germanium and silicon germanium represented by the chemical formula Si_{1-y}Ge_{y}. In both the chemical formulae above, x is 0 or more and less than 1, y is more than 0 and 1 or less, and x is smaller than y.

### BRIEF DESCRIPTION OF DRAWINGS

FIG. 1 is a schematic diagram of one example of an etching device illustrating one embodiment of an etching method according to the present invention.

### DESCRIPTION OF EMBODIMENTS

Hereinafter, one embodiment of the present invention will now be described. This embodiment illustrates one example of the present invention, and the present invention is not limited to this embodiment. This embodiment can be variously altered or improved, and such altered or improved aspects may also be included in the present invention.

An etching method according to this embodiment includes an etching step of bringing an etching gas containing nitrosyl fluoride (NOF) into contact with a member to be etched having an etching object subject to etching by the etching gas and a non-etching object not subject to etching by the etching gas, and selectively etching the etching object as compared with the non-etching object without using plasma.

In the etching method according to this embodiment, the etching object contains at least one of silicon and silicon germanium represented by the chemical formula Si₁₋ₓGeₓ , and the non-etching object contains at least one of germanium and silicon germanium represented by the chemical formula Si_{1-y}Ge_{y}. In both the chemical formulae, x is 0 or more and less than 1, y is more than 0 and 1 or less, and x is smaller than y.

When the etching gas is brought into contact with the member to be etched, the etching object and nitrosyl fluoride in the etching gas react with each other, and therefore the etching of the etching object proceeds. In contrast thereto, the non-etching object hardly reacts with nitrosyl fluoride as compared with the etching object, and therefore the etching of the non-etching object is difficult to proceed. Thus, the etching method according to this embodiment can selectively etch the etching object as compared with the non-etching object (i.e., high etching selectivity is obtained).

For example, the etching selectivity ratio which is the ratio of the etching rate of the etching object to the etching rate of the non-etching object can be set to 10 or more. The etching selectivity ratio is preferably 30 or more and more preferably 50 or more.

When both the etching object and the non-etching object contain silicon germanium, a difference y-x between x in the chemical formula Si₁₋ₓGeₓ and y in the chemical formula Si_{1-y}Ge_{y} is preferably 0.05 or more, more preferably 0.1 or more, still more preferably 0.2 or more, and particularly preferably 0.3 or more. When the y-x value falls within the ranges above, the etching selectivity ratio is easily set to the values above.

Further, the etching method according to this embodiment can etch the etching object without using plasma, which eliminates the necessity of performing etching using an expensive plasma generator. Therefore, the etching of the member to be etched can be performed at a low cost.

The etching method according to this embodiment described above can be utilized for producing a semiconductor element. More specifically, a method for producing a semiconductor element according to this embodiment is a method producing a semiconductor element using the etching method according to this embodiment, the member to be etched is a semiconductor substrate having the etching object and the non-etching object, and the method includes a treatment step of removing at least a part of the etching object from the semiconductor substrate by the etching.

The etching method according to this embodiment is usable for producing semiconductor elements, such as field-effect transistors, for example. By applying the etching method according to this embodiment to a laminate obtained by alternating laminating a polysilicon film and a silicon germanium film and formed with a groove extending along the laminating direction and penetrating the laminate, for example, the polysilicon film exposed to the inner surface of the groove is selectively and isotropically etched. Therefore, a structure in which an end portion of the silicon germanium film projects into the groove can be formed. A process of forming a structural body having such a structure is utilized for producing semiconductor elements, such as field-effect transistors, because the structural body can be utilized as a structural body of the semiconductor elements.

A process of forming the structure by etching has been conventionally performed by a wet etching method using chemicals. However, it is generally known that etching using an etching gas is superior to etching using chemicals in terms of microfabrication. Therefore, the etching method according to this embodiment can be expected to contribute to further miniaturization and higher integration of semiconductor elements.

Further, in the etching method according to this embodiment, the etching can be performed at low temperatures. Therefore, the etching method according to this embodiment is usable for producing semiconductor elements having circuits weak to heat, for example. There is concern that complementary metal oxide semiconductors (CMOS) and the like cause circuit damage when exposed to high temperatures in etching, for example. However, when the etching by the etching method according to this embodiment is adopted, the circuit damage due to heat is unlikely to occur.

When the non-etching object itself is utilized as the structural body of the semiconductor elements, materials that do not substantially react with nitrosyl fluoride or extremely slowly react with nitrosyl fluoride are used as the non-etching object. More specifically, at least one of germanium and silicon germanium represented by the chemical formula Si₁₋ₓGeₓ is usable as the non-etching object. In the chemical formula above, y is more than 0 and 1 or less.

Further, the etching method according to this embodiment can also be utilized for cleaning. For example, the cleaning can be performed by performing a step of forming a film containing a material containing silicon on a substrate and a step of etching the film of the material containing silicon formed on the substrate in a chamber, and then removing adhering substances containing silicon adhering to the inner surface of the chamber by the etching method according to this embodiment. In such cleaning, the chamber corresponds to the member to be etched, which is a component of the present invention, and the adhering substance corresponds to the etching object, which is a component of the present invention.

Hereinafter, the etching method according to this embodiment is described in more detail.

### Etching Gas

The etching gas is a gas containing nitrosyl fluoride, but may be a gas containing only nitrosyl fluoride or a mixed gas containing nitrosyl fluoride and other types of gases. When the etching gas is the mixed gas containing nitrosyl fluoride and other types of gases, the content of nitrosyl fluoride contained in the etching gas is preferably 1 vol % or more, more preferably 5 vol % or more and 80 vol % or less, still more preferably 10 vol % or more and 70 vol % or less, and particularly preferably 20 vol % or more and 60 vol % or less.

When the etching is performed with the content of nitrosyl fluoride contained in the etching gas set in the ranges above, the etching object can be more selectively etched as compared with the non-etching object. For example, the etching selectivity ratio which is the ratio of the etching rate of the etching object to the etching rate of the non-etching object can be set to 10 or more.

As the other types of gases constituting the etching gas together with a nitrosyl fluoride gas, a diluent gas and an additive gas are usable. More specifically, the etching gas can be a mixed gas containing nitrosyl fluoride and at least one of the diluent gas and the additive gas. Herein, the additive gas is a gas excluding nitrosyl fluoride and the diluent gas.

The diluent gas is suitably an inert gas, and specifically includes at least one selected from a nitrogen gas (N₂), helium (He), neon (Ne), argon (Ar), krypton (Kr), and xenon (Xe).

The content of the diluent gas contained in the etching gas is not particularly limited, and can be set to more than 0 vol % and 99 vol % or less.

The additive gas includes nitrogen oxides, such as nitric oxide (NO) and nitrous oxide (N₂O). The use of the mixed gas containing the additive gas as the etching gas increases the etching selectivity ratio in some cases.

The content of the additive gas contained in the etching gas is not particularly limited, and is preferably set to 0 vol % or more and 50 vol % or less, more preferably set to more than 0 vol % and 10 vol % or less, and still more preferably set to 1 vol % or more and 7 vol % or less.

The inclusion of metal components in the etching gas poses a possibility that the member to be etched is contaminated with the metal components. Therefore, the etching gas preferably contains no metal components, and the metal component content is preferably 1 mass ppm or less, for example. Examples of the metal components include chromium (Cr), molybdenum (Mo), iron (Fe), cobalt (Co), nickel (Ni), tungsten (W), aluminum (Al), copper (Cu), manganese (Mn), and the like.

The metal components can be removed from the etching gas by treatment of distilling the etching gas or by treatment of bringing the etching gas into contact with an adsorbent. Examples of the adsorbent include fluorides of metals belonging to Group 1 or 2 of the periodic table. Such treatment can reduce the metal component content in the etching gas to 1 mass ppm or less.

### Pressure Condition of Etching Step

A pressure condition of the etching step in the etching method according to this embodiment is not particularly limited insofar as the etching object is selectively etched as compared with the non-etching object, and is preferably set to 1 Pa or more and 80 kPa or less, more preferably set to 100 Pa or more and 55 kPa or less, still more preferably set to 1 kPa or more and 40 kPa or less, and particularly preferably set to 5 kPa or more and 20 kPa or less.

For example, the member to be etched is placed in a chamber, and can be etched while the etching gas is circulated through the chamber. The pressure in the chamber when the etching gas is circulated can be set to 1 Pa or more and 80 kPa or less. The flow rate of the etching gas may be set as appropriate such that the pressure in the chamber is kept constant according to the size of the chamber or the capacity of an exhaust facility reducing the pressure in the chamber.

### Temperature Condition Of Etching Step

The temperature condition of the etching step in the etching method according to this embodiment is not particularly limited, and is preferably set to −100°° C. or more and 100°° C. or less, more preferably set to −80° C. or more and 80° C. or less, still more preferably set to −60° C. or more and 50° C. or less, and particularly preferably set to −50° C. or more and 40° C. or less.

When the temperature condition falls within the ranges above, the etching object can be more selectively etched as compared with the non-etching object, and the etching selectivity ratio which is the ratio of the etching rate of the etching object to the etching rate of the non-etching object can be made higher. Herein, the temperature of the temperature condition is the temperature of the member to be etched. However, the temperature of a stage installed in a chamber of an etching device and supporting the member to be etched is also usable.

Under a condition where no plasma is generated and under the predetermined temperature condition (e.g., 50° C. or less), the progress of the reaction of nitrosyl fluoride with the non-etching object, such as germanium, silicon germanium, silicon oxide, silicon nitride, photoresist, and amorphous carbon, is slower than the progress of the reaction of nitrosyl fluoride with the etching object. Therefore, when the member to be etched has both the etching object and the non-etching object, the use of the etching method according to this embodiment allows the etching object to be selectively etched while the non-etching object is hardly etched.

Therefore, the etching method according to this embodiment can be utilized for a method for processing the etching object into a predetermined shape utilizing the non-etching object after patterned as a mask, a method for removing the etching object from a structural body having the etching object and the non-etching object, and the like.

### Member to be Etched

The member to be etched subject to the etching by the etching method according to this embodiment has the etching object and the non-etching object, and may be a member having a part formed of the etching object and a part formed of the non-etching object or may be a member formed of a mixture of the etching object and the non-etching object. The member to be etched may also have something other than the etching object and the non-etching object.

The shape of the member to be etched is not particularly limited, and may be a plate shape, a foil shape, a film shape, a powder shape, or a block shape, for example. Examples of the member to be etched include the semiconductor substrate described above.

### Etching Object

The etching object contains at least one of silicon and silicon germanium, and may be one formed of only at least one of silicon and silicon germanium, may be one having a part formed of only at least one of silicon and silicon germanium and a part formed of other materials, or may be one formed of a mixture of at least one of silicon and silicon germanium and other materials.

Herein, silicon is a compound containing silicon atoms (compound represented by the chemical formula Si₁₋ₓGeₓ, in which x in the chemical formula above is 0). Examples include monocrystalline silicon, polysilicon, and amorphous silicon. Silicon germanium is a compound containing silicon and germanium and is represented by the chemical formula Si₁₋ₓGeₓ. X in the chemical formula above is more than 0 and less than 1, preferably more than 0 and 0.1 or less, more preferably more than 0 and 0.07 or less, and still more preferably more than 0 and 0.05 or less. When both the etching object and the non-etching object contain silicon germanium, x in both the chemical formulae representing silicon germanium is smaller than y.

The proportion of the silicon atoms in all atoms constituting the etching object is preferably 95 mass % or more, more preferably 97 mass % or more, and still more preferably 99 mass % or more.

Further, the etching object may also contain atoms other than silicon and germanium to the extent that the effects of the present invention are not affected. For example, the effects of the present invention are obtained without any problem even when hydrogen atoms derived from a raw material of the polysilicon film are contained in the polysilicon film.

The shape of the etching object is not particularly limited, and may be a plate shape, a foil shape, a film shape, a powder shape, or a block shape, for example.

### Non-Etching Object

The non-etching object does not substantially react with nitrosyl fluoride or extremely slowly reacts with nitrosyl fluoride. Therefore, even when the etching is performed by the etching method according to this embodiment, the etching hardly proceeds. The non-etching object contains at least one of germanium and silicon germanium, and may be one formed of only at least one of germanium and silicon germanium, may be one having a part formed of only at least one of germanium and silicon germanium and a part formed of other materials, or may be one formed of a mixture of at least one of germanium and silicon germanium and other materials.

Herein, germanium is a compound containing germanium atoms (compound represented by the chemical formula Si_{1-y}Ge_{y}, in which y in the chemical formula above is 1). Examples include monocrystalline germanium, such as α-germanium and β-germanium, and amorphous germanium. Silicon germanium is a compound containing silicon and germanium and is represented by the chemical formula Si_{1-y}Ge_{y}. In the chemical formula above, y is more than 0 and less than 1, preferably more than 0.1 and less than 1, more preferably 0.2 or more and less than 1, still more preferably 0.25 or more and less than 1, and particularly preferably 0.3 or more and less than 1. When both the etching object and the non-etching object contain silicon germanium, x in both the chemical formulae representing silicon germanium is smaller than y.

Further, the non-etching object may contain atoms other than silicon and germanium to the extent that the effects of the present invention are not affected. For example, the effects of the present invention are obtained without any problem even when hydrogen atoms derived from a raw material of the silicon germanium film are contained in the silicon germanium film.

The non-etching object may contain, together with germanium and silicon germanium, silicon oxides (e.g., silicon dioxide (SiO₂)) containing silicon (Si) and oxygen (O), amorphous carbon, and photoresist.

The shape of the non-etching object is not particularly limited, and may be a plate shape, a foil shape, a film shape, a powder shape, or a block shape, for example.

The non-etching object is hardly etched by the etching method according to this embodiment, and therefore the non-etching object can suppress the etching of the etching object by the etching gas. Therefore, the non-etching object is usable as a resist or a mask for suppressing the etching of the etching object by the etching gas or may be used as a material for forming a structural body.

Therefore, the etching method according to this embodiment can be utilized for a method for processing the etching object into a predetermined shape (e.g., processing the etching object of a film shape possessed by the member to be etched to have a predetermined thickness), for example, utilizing the non-etching object after patterned as a resist or a mask, and thus can be suitably used for producing semiconductor elements.

Further, the non-etching object is hardly etched, and therefore the non-etching object can suppress the etching of parts which are originally not to be etched of semiconductor elements, and can prevent the loss of the characteristics of the semiconductor elements by the etching.

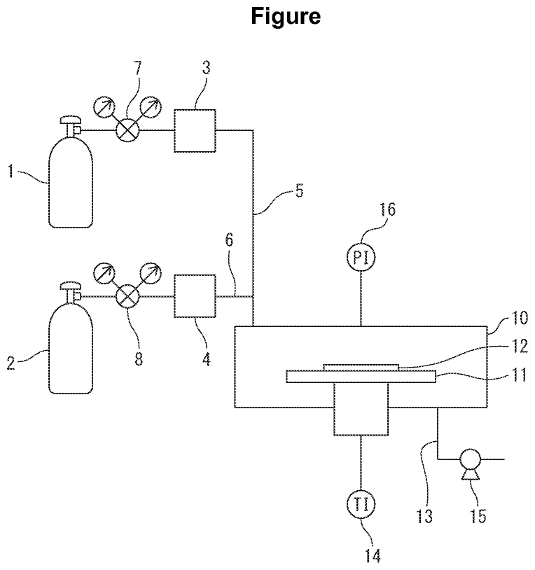

Next, one example of the configuration of an etching device capable of implementing the etching method according to this embodiment and one example of an etching method using the etching device are described with reference to FIG. 1. The etching device in FIG. 1 is an etching device capable of performing plasma-less etching not using plasma. First, the etching device in FIG. 1 is described.

The etching device in FIG. 1 includes a chamber 10 in which etching is performed, a stage 11 supporting a member to be etched 12 subject to etching inside the chamber 10, a thermometer 14 measuring the temperature of the member to be etched 12, exhaust piping 13 for exhausting gas inside the chamber 10, a vacuum pump 15 provided in the exhaust piping 13 and reducing the pressure inside the chamber 10, and a pressure gauge 16 measuring the pressure inside the chamber 10.

Further, the etching device in FIG. 1 includes an etching gas supply unit supplying the etching gas into the chamber 10. This etching gas supply unit includes a nitrosyl fluoride gas supply unit 1 supplying a nitrosyl fluoride gas, a diluent gas supply unit 2 supplying a diluent gas, nitrosyl fluoride gas supply piping 5 connecting the nitrosyl fluoride gas supply unit 1 and the chamber 10, and diluent gas supply piping 6 connecting the diluent gas supply unit 2 to a middle portion of the nitrosyl fluoride gas supply piping 5.

Further, the nitrosyl fluoride gas supply piping 5 includes a nitrosyl fluoride gas pressure control device 7 controlling the pressure of the nitrosyl fluoride gas and a nitrosyl fluoride gas flow rate control device 3 controlling the flow rate of the nitrosyl fluoride gas. Further, the diluent gas supply piping 6 includes a diluent gas pressure control device 8 controlling the pressure of the diluent gas and a diluent gas flow rate control device 4 controlling the flow of the diluent gas.

When the nitrosyl fluoride gas is supplied as the etching gas to the chamber 10, the nitrosyl fluoride gas is sent from the nitrosyl fluoride gas supply unit 1 to the nitrosyl fluoride gas supply piping 5, so that the nitrosyl fluoride gas is supplied to the chamber 10 via the nitrosyl fluoride gas supply piping 5.

When a mixed gas of the nitrosyl fluoride gas and the diluent gas, such as an inert gas, is supplied as the etching gas, the nitrosyl fluoride gas is sent from the nitrosyl fluoride gas supply unit 1 to the nitrosyl fluoride gas supply piping 5 and the diluent gas is sent from the diluent gas supply unit 2 to the nitrosyl fluoride gas supply piping 5 via the diluent gas supply piping 6. Thus, the nitrosyl fluoride gas and the diluent gas are mixed to form a mixed gas in the middle portion of the nitrosyl fluoride gas supply piping 5, and the mixed gas is supplied to the chamber 10 via the nitrosyl fluoride gas supply piping 5. However, it may be acceptable that the nitrosyl fluoride gas and the diluent gas are separately supplied to the chamber 10 and form a mixed gas in the chamber 10.

The configurations of the nitrosyl fluoride gas supply unit 1 and the diluent gas supply unit 2 are not particularly limited, and may be bottles or cylinders, for example. As the nitrosyl fluoride gas flow rate control device 3 and the diluent gas flow rate control device 4, mass flow controllers, flow meters, and the like can be utilized, for example.

When the etching gas is supplied to the chamber 10, the etching gas is preferably supplied while the supply pressure (i.e., value of the nitrosyl fluoride gas pressure control device 7 in FIG. 1) is maintained at a predetermined value. More specifically, the supply pressure of the etching gas is preferably set to 20 kPa or more and 1500 kPa or less, more preferably set to 40 kPa or more and 700 kPa or less, and still more preferably set to 60 kPa or more and 400 kPa or less.

When the supply pressure of the etching gas falls within the ranges above, the supply of the etching gas to the chamber 10 is smoothly performed and a load on the components (e.g., the various devices and the piping described above) of the etching device in FIG. 1 is small.

The pressure of the etching gas supplied into the chamber 10 is preferably set to 0.1 Pa or more and 80 kPa or less, more preferably set to 100 Pa or more and 55 kPa or less, and still more preferably set to 1.3 kPa or more and 40 kPa or less. When the pressure of the etching gas in the chamber 10 falls within the ranges above, a sufficient etching rate is obtained and the etching selectivity ratio is likely to be high.

The pressure in the chamber 10 before the etching gas is supplied is not particularly limited insofar as the pressure is equal to or lower than the supply pressure of the etching gas or is lower than the supply pressure of the etching gas. For example, the pressure is preferably 0.1 Pa or more and less than 40 kPa and more preferably 10 Pa or more and 20 kPa or less.

A difference between the supply pressure of the etching gas and the pressure in the chamber 10 before the etching gas is supplied is preferably 1.5 MPa or less, more preferably 0.6 MPa or less, and still more preferably 0.2 MPa or less. When the difference falls within the ranges above, the supply of the etching gas to the chamber 10 is likely to be smoothly performed.

When the etching gas is supplied to the chamber 10, the etching gas is preferably supplied while the temperature of the etching gas is maintained at a predetermined value. More specifically, the supply temperature of the etching gas is preferably −50° C. or more and 100°° C. or less.

The temperature of the member to be etched 12 when the etching is performed is preferably set to −100° C. or more and 100°° C. or less, more preferably set to −80°° C. or more and 80°° C. or less, still more preferably set to −60°° C. or more and 50° C. or less, and particularly preferably set to −50° C. or more and 40° C. or less. When the temperature falls within this temperature range, the etching of the etching object possessed by the member to be etched 12 smoothly proceeds, a load on the etching device is small, and the life of the etching device is likely to be long.

The etching treatment time (hereinafter sometimes also referred to as “etching time”) can be optionally set depending on the desired etching degree of the etching object possessed by the member to be etched 12. Considering the production efficiency of a semiconductor element production process, the etching treatment time is preferably within 180 minutes, more preferably within 120 minutes, still more preferably within 60 minutes, and particularly preferably within 40 minutes. The etching treatment time refers to the time from when the etching gas is introduced into the chamber 10 until when the etching gas inside the chamber 10 is exhausted to finish the etching.

The etching method according to this embodiment can be implemented using common etching devices used in a semiconductor element production process, such as the etching device in FIG. 1, and the configuration of the usable etching device is not particularly limited.

For example, the positional relationship between the nitrosyl fluoride gas supply piping 5 and the member to be etched 12 is not particularly limited insofar as the etching gas can be brought into contact with the member to be etched 12. Also with respect to the configuration of a temperature adjustment mechanism of the chamber 10, it is sufficient that the temperature of the member to be etched 12 can be adjusted to an optional temperature. Therefore, a configuration may be acceptable in which the temperature adjustment mechanism of the member to be etched 12 is directly provided on the stage 11 or the chamber 10 may be heated or cooled from the outside of the chamber 10 with an external temperature adjuster.

A material of the etching device in FIG. 1 is not particularly limited insofar as it has corrosion resistance to nitrosyl fluoride and can reduce the pressure to a predetermined pressure. For parts in contact with the etching gas, metals, such as yttrium (Y), nickel, nickel-based alloys, aluminum (Al), stainless steel, and platinum (Pt), compounds of these metals (e.g., metal fluorides, metal nitrides, metal oxides), ceramics, such as alumina, fluororesin, fluororubber, and the like are usable, for example.

Specific examples of the nickel-based alloys include Inconel (registered trademark), Hastelloy (registered trademark), Monel (registered trademark), and the like. Examples of the fluororesin include polytetrafluoroethylene (PTFE), polychlorotrifluoroethylene (PCTFE), tetrafluoroethylene-perfluoroalkoxyethylene copolymer (PFA), polyvinylidene fluoride (PVDF), and the like. Examples of the fluororubber include Viton (registered trademark), Kalrez (registered trademark), and the like.

### EXAMPLES

The present invention is described in more detail with reference to Examples and Comparative Examples described below.

### Example 1

Samples to be etched were etched using an etching device having substantially the same configuration as that of the etching device in FIG. 1. The samples to be etched used in Example 1 are described. One having a polysilicon film having a film thickness of 500 nm formed on the surface of a disk-shaped silicon wafer having a diameter of 100 mm (manufactured by Seiren KST Corp.) and one having a silicon germanium (Si_{0.7}Ge_{0.3}) film having a film thickness of 100 nm formed on the surface of a disc-shaped silicon wafer having a diameter of 100 mm (manufactured by Seiren KST Corp.) were individually prepared.

Then, these two types of samples to be etched were placed side by side on a stage inside a chamber of the etching device, and the stage temperature was reduced to 20° C. Next, a nitrosyl fluoride gas having a flow rate of 10 mL/min and argon having a flow rate of 90 mL/min were mixed to form a mixed gas, and the mixed gas was used as the etching gas. Then, the etching gas was supplied into the chamber at a flow rate of 100 mL/min and circulated for 1 minute for etching. The pressure inside the chamber when the etching gas was circulated was set to 6.7 kPa, and the partial pressure of the nitrosyl fluoride gas was set to 0.67 kPa.

Thus, the polysilicon film and the silicon germanium film of the two types of the samples to be etched above were etched. After the circulation of the etching gas was completed, the cooling of the stage was finished and the inside of the chamber was replaced with argon. After the etching was completed, the chamber was opened and the samples to be etched were taken out, and the film thickness of each of the polysilicon film and the silicon germanium film was measured. The film thickness of each of the polysilicon film and the silicon germanium film was measured using a F20 film thickness measurement system manufactured by Filmetrics. The film thickness measurement conditions are as follows.

Measurement pressure: Atmospheric pressure (101.3 kPa)

Measurement temperature: 28° C.

Measurement atmosphere: Atmosphere

Measurement wavelength range: 600 to 1100 nm

For each of the polysilicon film and the silicon germanium film, the etching rate (unit: nm/min) of each of the polysilicon and the silicon germanium was calculated by subtracting the film thickness (unit: nm) after the etching from the film thickness (unit: nm) before the etching and dividing the resultant film thickness by the etching time (unit: min). Then, the ratio (etching selectivity ratio) of the etching rate of the etching object (polysilicon) to the etching rate of the non-etching object (silicon germanium) was calculated. The results are shown in Table 1.

TABLE 1

| | | | Etching gas | | Stage | Pressure in | Etching rate (nm/min) | | |
|---|---|---|---|---|---|---|---|---|---|
| | Etching | Non-etching | | Flow | temperature | chamber | Etching | Non-etching | Etching |
| | object | object | Composition | rate *⁾ | (° C.) | (kPa) | object | object | selectivity ratio |
| Ex. 1 | Polysilicon | Si_{0.7}Ge_{0.3} | NOF/Ar | 10/90 | 20 | 6.7 | 35 | 3 | 12 |
| Ex. 2 | Polysilicon | Si_{0.7}Ge_{0.3} | NOF/Ar | 10/90 | 0 | 6.7 | 21 | 1 | 21 |
| Ex. 3 | Polysilicon | Si_{0.7}Ge_{0.3} | NOF/Ar | 10/90 | −20 | 6.7 | 15 | Less than 0.1 | More than 150 |
| Ex. 4 | Polysilicon | Si_{0.2}Ge_{0.8} | NOF/Ar | 10/90 | −20 | 6.7 | 15 | Less than 0.1 | More than 150 |
| Ex. 5 | Polysilicon | Si_{0.8}Ge_{0.2} | NOF/Ar | 10/90 | −20 | 6.7 | 15 | 0.3 | 50 |
| Ex. 6 | Polysilicon | Germanium | NOF/Ar | 10/90 | −20 | 6.7 | 15 | Less than 0.1 | More than 150 |
| Ex. 7 | Si_{0.95}Ge_{0.05} | Si_{0.7}Ge_{0.3} | NOF/Ar | 10/90 | −20 | 6.7 | 10 | Less than 0.1 | More than 100 |
| Ex. 8 | Polysilicon | Si_{0.7}Ge_{0.3} | NOF/Ar | 50/50 | −50 | 6.7 | 12 | 0.2 | 60 |
| Ex. 9 | Polysilicon | Si_{0.7}Ge_{0.3} | NOF/Ar | 10/90 | −20 | 20 | 40 | 0.5 | 80 |
| Ex. 10 | Polysilicon | Si_{0.7}Ge_{0.3} | NOF/Ar | 10/90 | 40 | 6.7 | 128 | 51 | 2.5 |
| Ex. 11 | Si_{0.5}Ge_{0.5} | Germanium | NOF/Ar | 10/90 | 40 | 6.7 | 10 | 3 | 3 |
| Ex. 12 | Polysilicon | Si_{0.7}Ge_{0.3} | NOF/NO/Ar | 10/5/85 | 0 | 6.7 | 21 | Less than 0.1 | More than 210 |
| Comp. Ex. 1 | Polysilicon | Si_{0.7}Ge_{0.3} | NO/F₂/Ar | 5/5/90 | −20 | 6.7 | 4 | 7 | 0.6 |
| Comp. Ex. 2 | Polysilicon | Si_{0.7}Ge_{0.3} | NO/ClF₃/Ar | 5/5/90 | 20 | 6.7 | 30 | More than 100 | Less than 0.3 |
| Comp. Ex. 3 | Polysilicon | Si_{0.7}Ge_{0.3} | NOF/ClF/Ar | 5/5/90 | −20 | 6.7 | 2 | 11 | 0.2 |
| Comp. Ex. 4 | Si_{0.5}Ge_{0.5} | Si_{0.7}Ge_{0.3} | NOF/Ar | 10/90 | 20 | 6.7 | 1 | 3 | 0.3 |

*⁾ The flow rate of the nitrosyl fluoride (NOF) gas and the diluent gas (Ar). A case where the flow rate of the nitrosyl fluoride gas is 10 mL/min and the flow rate of the diluent gas is 90 mL/min is indicated as 10/90.

### Examples 2 to 12 and Comparative Examples 1 to 4

Five types of samples to be etched were etched in the same manner as in Example 1, except that the flow rates of the nitrosyl fluoride gas and argon, the stage temperature, and the pressure inside the chamber were as shown in Table 1, and the etching rates of polysilicon, silicon germanium, and germanium and the ratios of the etching rates were individually calculated. The results are shown in Table 1.

The samples to be etched used in Examples 5 to 7 and Example 11 were those having the Si_{0.8}Ge_{0.2} film, the Si_{0.2}Ge_{0.8} film, the Si_{0.95}Ge_{0.05} film, the Si_{0.5}Ge_{0.5} film, or the germanium film formed on the surface of a disc-shaped silicon wafer having a diameter of 100 mm and are all manufactured by Seiren KST Corp.

The results of Examples 1 to 3, Example 10, and Example 12 show that polysilicon is selectively etched as compared with silicon germanium when the etching temperature (stage temperature) is −20° C. or more and 40°° C. or less. With a decrease in the etching temperature, the etching selectivity ratio which is the ratio of the etching rate of the etching object to the etching rate of the non-etching object was improved.

When the etching temperature (stage temperature) was −20° C. or more and 20° C. or less, the etching selectivity ratio was particularly high. When the etching temperature was 40° C., the etching selectivity ratio was slightly low.

When the mixed gas containing nitric oxide was used as the etching gas, the etching selectivity ratio was increased.

The results of Examples 3 to 6 show that, when the content of germanium in the non-etching object is 20 mol % or more, polysilicon is selectively etched as compared with silicon germanium.

The results of Example 7 show that, even when 5 mol % of germanium is contained in silicon germanium as the etching object, the etching object is selectively etched as compared with silicon germanium containing 30 mol % of germanium (non-etching object).

The results of Examples 8, 9 show that, even when the proportion of nitrosyl fluoride in the etching gas is 50 vol % or even when the pressure in the chamber in the etching is 20 kPa, respectively, polysilicon is selectively etched as compared with silicon germanium.

The results of Example 11 show that, even when the etching object contains 50 mol % of germanium, the etching object is selectively etched as compared with amorphous germanium.

The results of Comparative Examples 1 to 3 show that the mixed gas of nitric oxide, fluorine gas, and argon, the mixed gas containing nitric oxide, chlorine trifluoride (ClF₃), and argon, and the mixed gas of nitric oxide, chlorine monofluoride (ClF), and argon, respectively, were used as the etching gas, silicon germanium was preferentially etched as compared with polysilicon. This shows that, even when the mixed gas containing nitric oxide and a fluorine atom-containing gas is used as the etching gas, the selective etching in which polysilicon is selectively etched as compared with silicon germanium cannot be realized.

The results of Comparative Example 4 show that, when both the etching object and the non-etching object are silicon germanium, the larger the germanium proportion, the lower the etching rate, and thus silicon germanium having a larger germanium proportion is not suitable as the etching object.

### REFERENCE SIGNS LIST

1 . . . nitrosyl fluoride gas supply unit
2 . . . diluent gas supply unit
3 . . . nitrosyl fluoride gas flow rate control device
4 . . . diluent gas flow rate control device
5 . . . nitrosyl fluoride gas supply piping
6 . . . diluent gas supply piping
7 . . . nitrosyl fluoride gas pressure control device
8 . . . diluent gas pressure control device
10 . . . chamber
11 . . . stage
12 . . . member to be etched
13 . . . exhaust piping
14 . . . thermometer
15 . . . vacuum pump
16 . . . pressure gauge

1. An etching method comprising:
an etching step of bringing an etching gas containing nitrosyl fluoride into contact with a member to be etched having an etching object subject to etching by the etching gas and a non-etching object not subject to etching by the etching gas, and selectively etching the etching object as compared with the non-etching object without using plasma, wherein
the etching object contains at least one of silicon and silicon germanium represented by a chemical formula Si₁₋ₓGeₓ and the non-etching object contains at least one of germanium and silicon germanium represented by a chemical formula Si_{1-y}Ge_{y}, and
in both the chemical formulae, x is 0 or more and less than 1, y is more than 0 and 1 or less, and x is smaller than y.

2. The etching method according to claim 1, wherein x in the chemical formula is 0 or more and 0.1 or less.

3. The etching method according to claim 1, wherein y in the chemical formula is more than 0.1 and 1 or less.

4. The etching method according to claim 1, wherein y in the chemical formula is 0.2 or more and 1 or less.

5. The etching method according to claim 1, wherein a temperature condition of the etching step is −50° C. or more and 40° C. or less.

6. The etching method according to claim 1, wherein the etching gas is a gas containing only nitrosyl fluoride or a mixed gas containing nitrosyl fluoride and a diluent gas.

7. The etching method according to claim 6, wherein the diluent gas is at least one selected from a nitrogen gas, helium, argon, neon, krypton, and xenon.

8. A method for producing a semiconductor element, the method producing a semiconductor element using the etching method according to claim 1, and
the member to be etched being a semiconductor substrate having the etching object and the non-etching object,
the method comprising:
a treatment step of removing at least a part of the etching object from the semiconductor substrate by the etching.

9. The etching method according to claim 2, wherein y in the chemical formula is more than 0.1 and 1 or less.

10. The etching method according to claim 2, wherein a temperature condition of the etching step is −50°° C. or more and 40° C. or less.

11. The etching method according to claim 3, wherein a temperature condition of the etching step is −50° C. or more and 40° C. or less.

12. The etching method according to claim 4, wherein a temperature condition of the etching step is −50° C. or more and 40° C. or less.

13. The etching method according to claim 2, wherein the etching gas is a gas containing only nitrosyl fluoride or a mixed gas containing nitrosyl fluoride and a diluent gas.

14. The etching method according to claim 3, wherein the etching gas is a gas containing only nitrosyl fluoride or a mixed gas containing nitrosyl fluoride and a diluent gas.

15. The etching method according to claim 4, wherein the etching gas is a gas containing only nitrosyl fluoride or a mixed gas containing nitrosyl fluoride and a diluent gas.

16. The etching method according to claim 5, wherein the etching gas is a gas containing only nitrosyl fluoride or a mixed gas containing nitrosyl fluoride and a diluent gas.

17. A method for producing a semiconductor element, the method producing a semiconductor element using the etching method according to claim 2, and
the member to be etched being a semiconductor substrate having the etching object and the non-etching object,
the method comprising:
a treatment step of removing at least a part of the etching object from the semiconductor substrate by the etching.

18. A method for producing a semiconductor element, the method producing a semiconductor element using the etching method according to claim 3, and
the member to be etched being a semiconductor substrate having the etching object and the non-etching object,
the method comprising:
a treatment step of removing at least a part of the etching object from the semiconductor substrate by the etching.

19. A method for producing a semiconductor element, the method producing a semiconductor element using the etching method according to claim 4, and the member to be etched being a semiconductor substrate having the etching object and
the non-etching object,
the method comprising:
a treatment step of removing at least a part of the etching object from the semiconductor substrate by the etching.

20. A method for producing a semiconductor element, the method producing a semiconductor element using the etching method according to claim 5, and
the member to be etched being a semiconductor substrate having the etching object and the non-etching object,
the method comprising:
a treatment step of removing at least a part of the etching object from the semiconductor substrate by the etching.
